(19) United States
(12) Patent Application Publication
(10) Pub. No.: US 2008/0191618 A1
(43) Pub. Date: Aug. 14, 2008

(54) ORGANIC ELECTROLUMINESCENCE DEVICE

(76) Inventor: Masayuki Mishima, Kanagawa (JP)

Correspondence Address: BIRCH STEWART KOLASCH & BIRCH, PO BOX 747, FALLS CHURCH, VA, 22040-0747, US

(21) Appl. No.: 12/024,924

(22) Filed: Feb. 1, 2008

(30) Foreign Application Priority Data
Feb. 13, 2007 (JP) 2007-032587

(51) Int. Cl. H01L 51/50

(52) U.S. Cl. 313/504

(57) ABSTRACT

An organic electroluminescence device includes at least one light-emitting layer between a pair of opposing electrodes, wherein: the light-emitting layer includes at least a light-emitting material and at least two host materials, an Ip value of a first host material is larger than an Ip value of a second host material, a hole mobility of the first host material is larger than a hole mobility of the second host material, and a content of the second host material is 1% to 20% by weight of the total amount of host materials. An organic EL device having high emission efficiency and excellent in drive durability can be provided.

### CROSS-REFERENCE TO RELATED APPLICATION

This application claims priority under 35 USC 119 from Japanese Patent Application No. 2007-032587, the disclosure of which is incorporated by reference herein.

### BACKGROUND OF THE INVENTION

1. Field of the Invention

The present invention relates to an organic electroluminescence device (which is referred to hereinafter as an “organic EL device” in some cases), and more particularly to an organic EL device having high light-emission efficiency and excellent in drive durability.

2. Description of the Related Art

Organic electroluminescence devices, containing a thin film material that emits light by excitation due to supply of current, are known. The organic electroluminescence devices are capable of providing a light emission of a high luminance at a low voltage, and therefore have broad potential applications in fields such as cellular phone displays, personal digital assistants (PDA), computer displays, car information displays, TV monitors and ordinary illumination, and also have advantages of reducing the thickness, weight, size and power consumption of the devices in the respective fields. Accordingly, such devices are greatly expected to become the leading devices in the future electronic display market. However, there are still many technical problems to be overcome, such as with respect to luminance and color tone, durability under various ambient operating conditions, and mass productivity at low cost, in order for these devices to be practically used in these fields in place of the conventional display devices.

Particularly important issues include an improvement in the light emission efficiency and an improvement in the drive durability. In the aforementioned various devices, realization of a higher luminance has been a first issue for realizing reductions in the thickness, weight and size of the device. In realizing reductions in the thickness and weight of the device, reductions in the size and weight are required not only in the device but also in a driving power source. Particularly when the electric power is supplied from a primary battery or a secondary battery, power saving is an important issue, and it is strongly desired to obtain a high luminance at a low drive voltage. In the past, a higher voltage has been required in order to obtain a higher luminance, thus having resulted in an increased electric power consumption. Also, a higher luminance and a higher voltage have resulted in a deterioration of the durability of the device.

For example, Japanese Patent Application Laid-Open (JP-A) No. 2006-135295 proposes a technology of employing a phosphorescent dopant and two or more phosphorescent host materials as the light-emitting layer. The two phosphorescent host materials preferably have a difference in the triplet energy level of from 2.3 eV to 3.5 eV and are used in a mixing ratio of from 3:1 to 1:3 by weight ratio. However, the combined use of two such host materials is unable to provide a sufficient improvement in the light emission efficiency and in the drive durability.

Also JP-A No. 2000-106277 proposes to use an aromatic polycyclic hydrocarbon compound, a light emission material including a fluorescent dye and a host material as the light-emitting layer. The aromatic polycyclic hydrocarbon compound has a faster hole mobility than in the host material, and is used for the purpose of suppressing accumulation of holes in the light-emitting layer. However, such a formulation is unable to provide a sufficient improvement in either of the light emission efficiency and the drive durability.

### SUMMARY OF THE INVENTION

The present invention has been made in view of the above circumstances and provides an organic electroluminescence device with the following aspect.

An aspect of the invention is to provide an organic electroluminescence device, comprising at least one light-emitting layer between a pair of opposing electrodes, wherein: the light-emitting layer includes at least a light-emitting material and at least two host materials; an Ip value (ionization potential) of a first host material is larger than an Ip value of a second host material; a hole mobility of the first host material is larger than a hole mobility of the second host material; and a content of the second host material is 1% by weight to 20% by weight of the total amount of host materials.

### DETAILED DESCRIPTION OF THE INVENTION

An object of the present invention is to provide an organic EL device having high light-emission efficiency and excellent in drive durability.

The above mentioned object of the present invention has been achieved by an organic electroluminescence device comprising at least one light-emitting layer between a pair of opposing electrodes, wherein the light-emitting layer includes at least a light-emitting material and at least two host materials, an Ip value (ionization potential) of a first host material is larger than an Ip value of a second host material, a hole mobility of the first host material is larger than a hole mobility of the second host material, and a content of the second host material is 1% by weight to 20% by weight of the total amount of host materials.

Preferably, a difference in the Ip value (ΔIp) between the Ip value of the first host material and the Ip value of the second host material is from 0.2 eV to 1.0 eV.

Preferably, a ratio of the hole mobility of the first host material to the hole mobility of the second host material is from 2 to 10,000.

Preferably, the hole mobility of the light-emitting layer is from 1×10⁻⁷ cm²·V⁻¹·sec⁻¹ to 1×10⁻⁴ cm²·V₋₁·sec⁻¹, in the case that an electric field of 1×10⁶ V/cm is applied to the light-emitting layer.

Preferably, at least one of the light-emitting material is a phosphorescent material.

Preferably, the lowest triplet excitation level (T1) of at least one of the at least two host materials is higher than T1 of the phosphorescent material.

Preferably, the first host material is a carbazole compound, and the second host material is a carbazole compound, an azepine compound or a carbene complex compound.

More preferably, the first host material is a carbazole compound, the second host material is a carbazole compound, an azepine compound or a carbene complex compound, and a difference in the Ip value (ΔIp) between the Ip value of the first host material and the Ip value of the second host material is from 0.2 eV to 1.0 eV.

More preferably, the first host material is a carbazole compound, the second host material is a carbazole compound, an azepine compound or a carbene complex compound, and a ratio of the hole mobility of the first host material to the hole mobility of the second host material is from 2 to 10,000.

More preferably, the first host material is a carbazole compound, the second host material is a carbazole compound, an azepine compound or a carbene complex compound, and the hole mobility of the light-emitting layer is from 1×10⁻⁷ cm²·V⁻¹·sec⁻¹ to 1×10⁻⁴ cm²·V⁻¹·sec⁻¹, in the case that an electric field of 1×10⁶ V/cm is applied to the light-emitting layer.

More preferably, the first host material is a carbazole compound, the second host material is a carbazole compound, an azepine compound or a carbene complex compound, and at least one light-emitting material is a phosphorescent material.

Conventionally, two host materials have been used together to try to improve the drive durability. A mixing ratio of host materials used together is 3:1 to 1:3 by weight, that is, one of host materials is 25% to 75% by weight among all host materials, such that the respective host materials occupy major ratios. The inventors, as a result of conducting diligent research to find means of further improving the emission efficiency and the drive durability, found that an unexpectedly remarkable improvement could be achieved by selecting a specific range of Ip value, a specific range of hole mobility and a specific mixing ratio, which are completely different from those of combinations of host materials that have been conventionally known, and thereby the invention was made. The invention is characterized in that a second host material having a relatively small Ip value and a low hole mobility is added at a low content of 1% by weight to 20% by weight with respect to the total amount of host materials.

The present invention provides an organic EL device having high light-emission efficiency and excellent in drive durability.

The organic EL device of the present invention is explained below in detail.

(Constitution)

The organic electroluminescence device according to the present invention has at least one organic compound layer including a light-emitting layer between a pair of electrodes (anode and cathode), and further preferably has a hole transport layer between the anode and the light-emitting layer as well as an electron transport layer between the cathode and the light-emitting layer.

In view of the nature of a luminescence device, it is preferred that at least either electrode of the pair of electrodes is transparent.

As a lamination pattern of the organic compound layer according to the present invention, it is preferred that the layer includes in the order of a hole transport layer, a light-emitting layer, and electron transport layer from the anode side. Moreover, a hole injection layer is provided between the hole transport layer and the anode and/or an electron transporting intermediate layer is provided between the light-emitting layer and the electron transport layer. In addition, a hole transporting intermediate layer may be provided between the light-emitting layer and the hole transport layer, and similarly, an electron injection layer may be provided between the cathode and the electron transport layer.

The preferred modes of the organic compound layer in the organic electroluminescence device of the present invention are as follows. (1) An embodiment having a hole injection layer, a hole transport layer (the hole injection layer may also have the role of the hole transport layer), a hole transporting intermediate layer, a light-emitting layer, an electron transport layer, and an electron injection layer (the electron transport layer may also have the role of the electron injection layer) in this order from the anode side; (2) an embodiment having a hole injection layer, a hole transport layer (the hole injection layer may also have the role of the hole transport layer), a light-emitting layer, an electron transporting immediate layer, an electron transport layer, and an electron injection layer (the electron transport layer may also have the role of the electron injection layer); and (3) an embodiment having a hole injection layer, a hole transport layer (the hole injection layer may also have the role of the hole transport layer), a hole transporting intermediate layer, a light-emitting layer, an electron transporting intermediate layer, an electron transport layer, and an electron injection layer (the electron transport layer may also have the role of the electron injection layer).

The above-described hole transporting intermediate layer preferably has at least either a function for accelerating the injection of holes into the light-emitting layer, or a function for blocking electrons.

Furthermore, the above-described electron transporting intermediate layer preferably has at least either a function for accelerating the injection of electrons into the light-emitting layer, or a function for blocking holes.

Moreover, at least either of the above-described hole transporting intermediate layer and the electron transporting intermediate layer preferably has a function for blocking excitons produced in the light-emitting layer.

In order to realize effectively the functions for accelerating the injection of hole, or the injection of electrons, and the functions for blocking holes, electrons, or excitons, it is preferred that the hole transporting intermediate layer and the electron transporting intermediate layer are adjacent to the light-emitting layer.

The respective layers mentioned above may be separated into a plurality of secondary layers.

Next, the components constituting the organic electroluminescence device of the present invention will be described in detail.

The organic electroluminescence device of the present invention has at least one organic compound layer including a light-emitting layer. Examples of the layer included in the organic compound layers other than the light-emitting layer include, as mentioned above, respective layers of a hole injection layer, a hole transport layer, a hole transporting intermediate layer, a light-emitting layer, an electron transporting intermediate layer, an electron transport layer, an electron injection layer and the like.

The respective layers constituting the organic compound layer can be suitably formed in accordance with any of a dry film-forming method such as a vapor deposition method, or a sputtering method; a transfer method; a printing method; a coating method; an ink-jet printing method; or a spray method.

(Light-Emitting Layer)

The light-emitting layer is a layer having functions of receiving a hole from an anode, a hole injection layer, a hole transport layer or a hole-transport intermediate layer, also receiving an electron from a cathode, an electron injection layer, an electron transport layer or an electron-transport intermediate layer and providing a site for hole-electron recombination to cause a light emission, when an electric field is applied to the light-emitting layer.

The light-emitting layer in the invention includes at least a light-emitting material (light-emitting dopant) and a plurality of host materials.

The light-emitting layer may be formed by a single layer or by two or more layers, and the layers may emit lights with respectively different colors. In the case where the light-emitting layer is constituted of plural layers, each layer thereof preferably contains at least a light-emitting material and a plurality of host materials.

As the light-emitting material and a plurality of host compounds contained in the light-emitting layer in the invention, a combination of a fluorescent dopant by which light emission (fluorescence) from a singlet exciton can be obtained and a plurality of host compounds or a combination of a phosphorescent dopant by which light emission (phosphorescence) from a triplet exciton can be obtained and a plurality of host compounds may be used.

The light-emitting layer in the invention may contain two or more light-emitting materials to improve color purity or to expand a wavelength region of emitted light.

<Light-Emitting Material>

As the light-emitting material in the invention, both of a phosphorescent material and a fluorescent material may be used as a dopant. The phosphorescent material is preferred.

Further, it is preferred that the light-emitting material in the invention is, from the viewpoint of the drive durability, a dopant that satisfies the relationship with respect to the difference in Ip or Ea between the dopant and the host compound of 1.2 eV>ΔIp>0.2 eV and/or 1.2 eV>ΔEa>0.2 eV.

<<Phosphorescent Material>>

Examples of the phosphorescent light-emitting material are not limited specifically, but generally include complexes containing a transition metal atom or a lantanoid atom.

For instance, although the transition metal atom is not limited, it is preferably ruthenium, rhodium, palladium, tungsten, rhenium, osmium, iridium, or platinum; more preferably rhenium, iridium, or platinum; and even more preferably iridium or platinum.

Examples of the lantanoid atom include lanthanum, cerium, praseodymium, neodymium, samarium, europium, gadolinium, terbium, dysprosium, holmium, erbium, thulium, ytterbium, and lutetium, and among these lantanoid atoms, neodymium, europium, and gadolinium are preferred.

Examples of ligands in the complex include the ligands described, for example, in “Comprehensive Coordination Chemistry” authored by G. Wilkinson et al., published by Pergamon Press Company in 1987; “Photochemistry and Photophysics of Coordination Compounds” authored by H. Yersin, published by Springer-Verlag Company in 1987; and “YUHKI KINZOKU KAGAKU—KISO TO OUYOU—(Metalorganic Chemistry—Fundamental and Application—)” authored by Akio Yamamoto, published by Shokabo Publishing Co., Ltd. in 1982.

Specific examples of the ligands include preferably halogen ligands preferably chlorine ligands), aromatic carboxycyclic ligands (e.g., cyclopentadienyl anions, benzene anions, or naphthyl anions and the like), nitrogen-containing heterocyclic ligands (e.g., phenylpyridine, benzoquinoline, quinolinol, bipyridyl, or phenanthroline and the like), diketone ligands (e.g., acetylacetone and the like), carboxylic acid ligands (e.g., acetic acid ligands and the like), alcoholato ligands (e.g., phenolato ligands and the like), carbon monoxide ligands, isonitryl ligands, and cyano ligand, and more preferably nitrogen-containing heterocyclic ligands.

The above-described complexes may be either a complex containing one transition metal atom in the compound, or a so-called polynuclear complex containing two or more transition metal atoms wherein different metal atoms may be contained at the same time.

Among these, specific examples of the light-emitting material include phosphorescent light-emitting compounds described in patent documents such as U.S. Pat. No. 6,303,238B1, U.S. Pat. No. 6,097,147, International Patent Publication (WO) No. 00/57676, WO No. 00/70655, WO No. 01/08230, WO No.01/39234A2, WO No. 01/41512A1, WO No. 02/02714A2, WO No. 02/15645A1, WO No. 02/44189A1, JP-A No. 2001-247859, Japanese Patent Application No. 2000-33561, JP-A Nos. 2002-117978, 2002-225352, and 2002-235076, Japanese Patent Application No. 2001-239281, JP-A No. 2002-170684, European Patent (EP) No. 1211257, JP-A Nos. 2002-226495, 2002-234894, 2001-247859, 2001-298470, 2002-173674, 2002-203678, 2002-203679, 2004-357791, 2006-256999, 2007-19462, etc. Among these, more preferable light-emitting materials which satisfy the relationship of (2) are an Ir complex, Pt complex, Cu complex, Re complex, W complex, Rh complex, Ru complex, Pd complex, Os complex, Eu complex, Tb complex, Gd complex, Dy complex and Ce complex. Particularly preferable are an Ir complex, Pt complex and Re complex, complex, each of which including at least one coordination mode from among metal-carbon bond, metal-nitrogen bond, etal-oxygen bond and metal-sulfur bond are preferred.

<<Fluorescent Light-Emitting Material>>

Examples of the above-described fluorescent light-emitting material generally include, for example, benzoxazole derivatives, benzimidazoles derivatives, benzothiazole derivatives, styrylbenzene derivatives, polyphenyl derivatives, diphenylbutadiene derivatives, tetraphenylbutadiene derivatives, naphthalimide derivatives, coumalin derivatives, pyrane derivatives, perinone derivatives, oxadiazole derivatives, aldazine derivatives, pyralidine derivatives, cyclopentadiene derivatives, bis-styrylanthracene derivatives, quinacridone derivatives, pyrrolopyridine derivatives, thiadiazolopyridine derivatives, cyclopentadiene derivatives, styrylamine derivatives, aromatic dimethylidene compounds, condensed polycyclic aromatic compounds (fore example, anthracene, phenanthroline, pyrene, perylene, rubrene, pentacene, or the like), a variety of metal complexes represented by metal complexes or rare-earth complexes of 8-quinolynol, polymer compounds such as polythiophene, polyphenylene and polyphenylenevinylene, organic silanes, and the like.

Specific examples of the light-emitting materials will be given below, but it should not be construed that the invention is limited thereto.

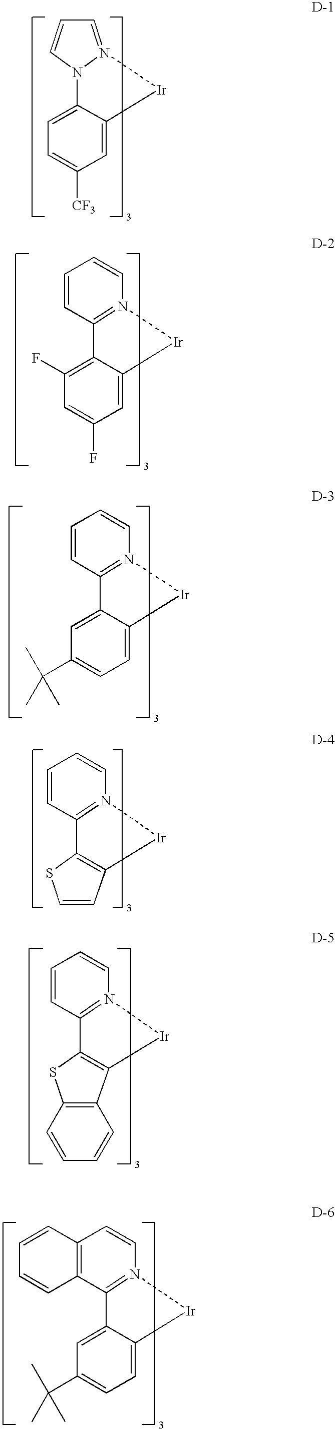

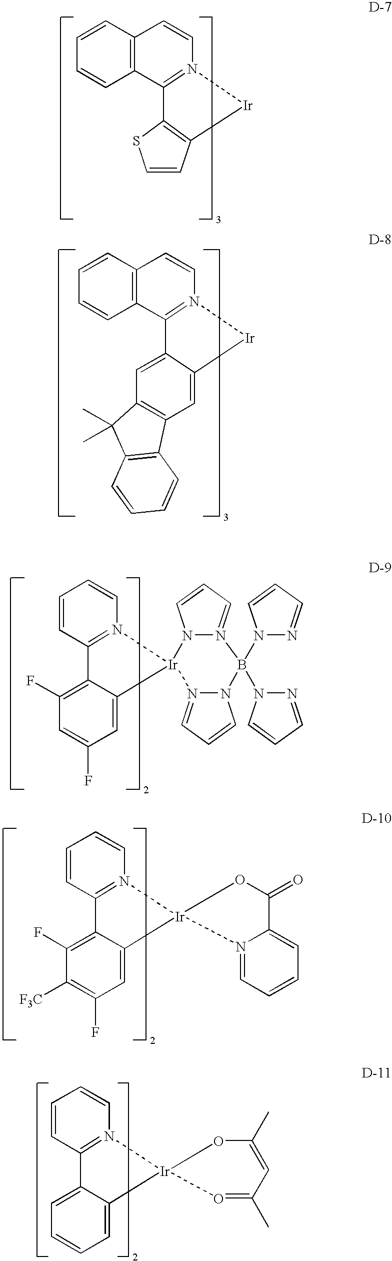

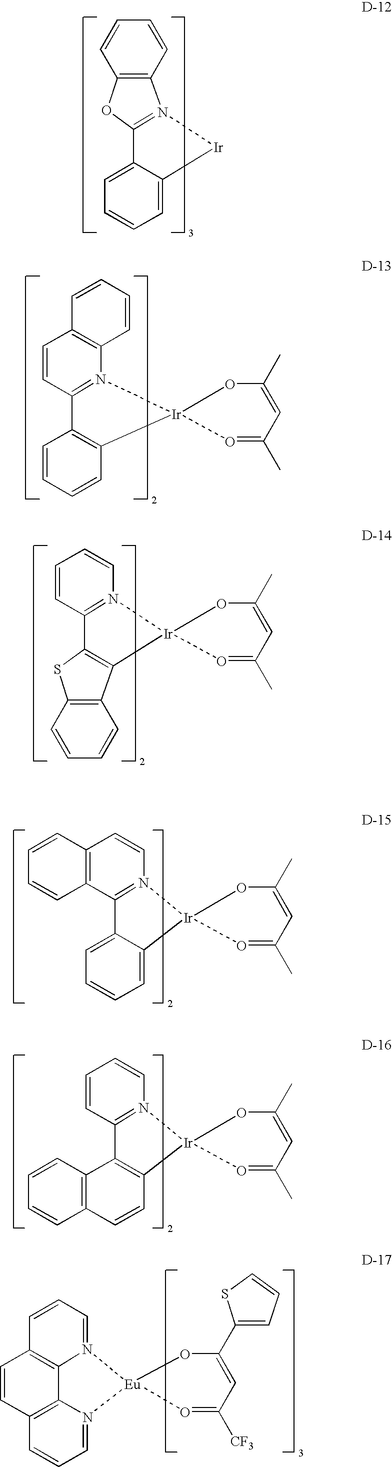

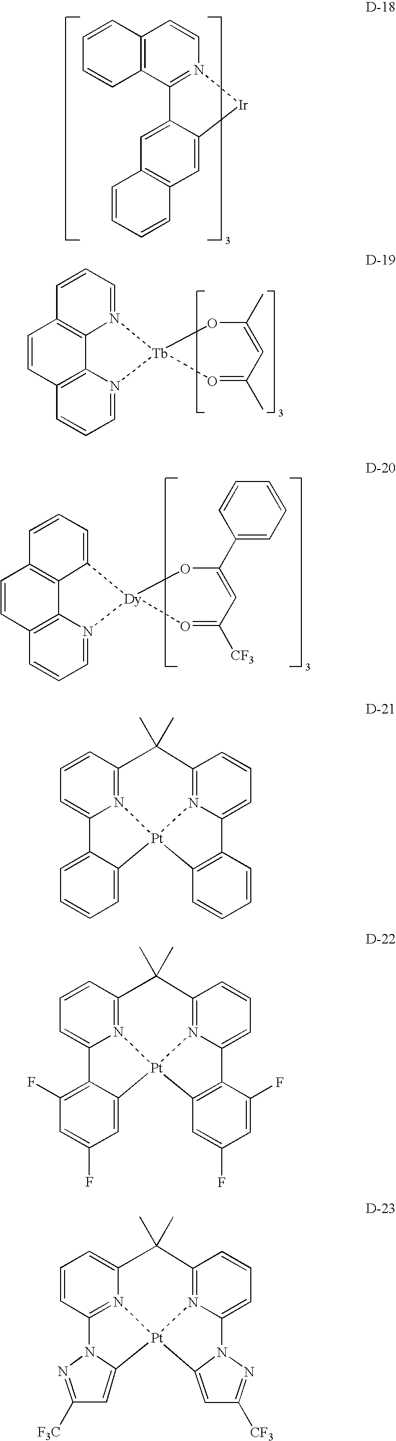

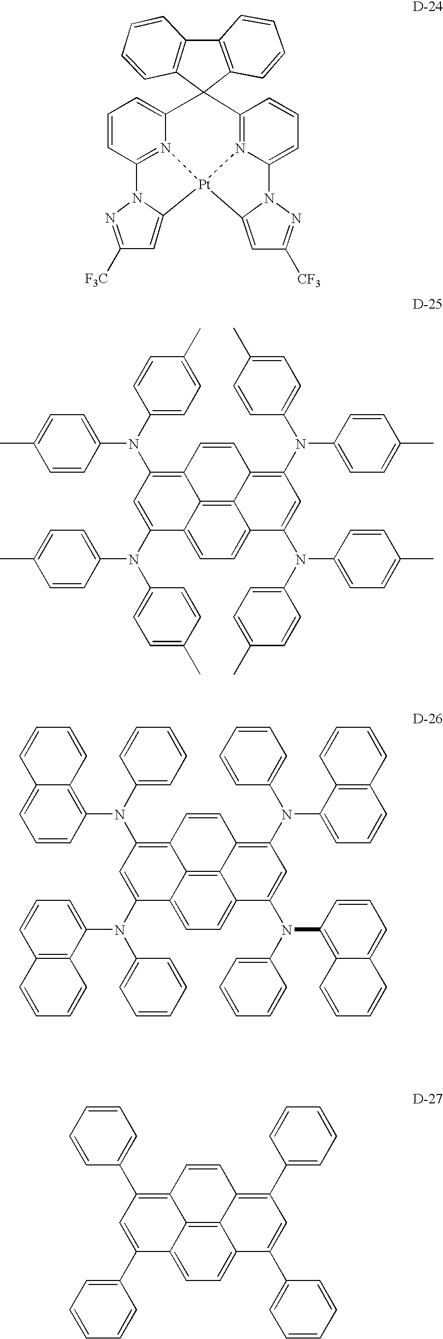

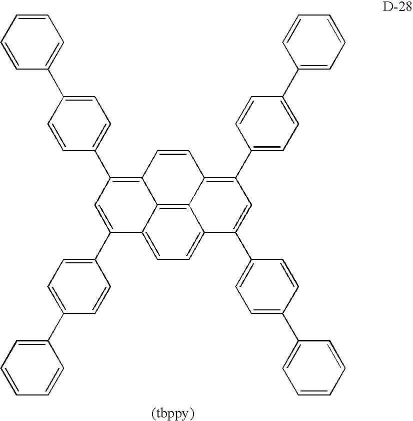

Among the above-described compounds, as the light-emitting materials to be used in the present invention, D-2, D-3, D-4, D-5, D-6, D-7, D-8, D-9, D-10, D-11, D-12, D-13, D-14, D-15, D-16, D-21, D-22, D-23, D-24, or D-25 to D-28 is preferable, D-2, D-3, D-4, D-5, D-6, D-7, D-8, D-12, D-14, D-15, D-16, D-21, D-22, D-23, D-24, or D-25 to D-28 is more preferable, and D-21, D-22, D-23, D-24, or D-25 to D-28 is further preferable in view of light-emission efficiency, and durability.

The light-emitting material in a light-emitting layer is contained in an amount of 0.1% by weight to 50% by weight with respect to the total mass of the compounds generally forming the light-emitting layer, but it is preferably contained in an amount of 1% by weight to 40% by weight, and more preferably in an amount of 2% by weight to 15% by weight in view of durability and light-emission efficiency.

Although a thickness of the light-emitting layer is not particularly limited, 1 nm to 500 nm is usually preferred, and within this range, 5 nm to 200 nm is more preferable, and 5 nm to 100 nm is even more preferred in view of light-emission efficiency.

<Host Material>

In the invention, a light-emitting layer includes at least two host materials. Both of the at least two host materials are hole transporting hosts, an Ip value of the fist host material is larger than the Ip value of the second host material, and the hole mobility of the first host material is larger than the hole mobility of the second host material. Furthermore, a content of the second host material is 1% by weight to 20% by weight of the total amount of host materials.

Preferably, a difference in Ip value (ΔIp) between the Ip value of the first host material and the Ip value of the second host material is from 0.2 eV to 1.0 eV. More preferably, the ΔIp is from 0.3 eV to 0.9 eV, and even more preferably, the ΔIp is from 0.3 eV to 0.7 eV.

ΔIp=Ip (first host material)−Ip (second host material)

Preferably, a ratio of a hole mobility of the first host material to a hole mobility of the second host material is from 2 to 10,000. The ratio is more preferably from 2to 1,000 and still more preferably from 2 to 100.

As the host materials are combined like this, the hole mobility in a light-emitting layer can be made smaller in comparison with the case, wherein only one host material is used, thereby an emission region can be expanded over the entire light-emitting layer, and thereby light emission efficiency can be increased and the drive durability can be improved.

The hole mobility of the light-emitting layer in the invention is preferably from 1×10⁻⁷ cm²·V⁻¹·sec⁻¹ to 1×10⁻⁴ cm²·V⁻¹·sec⁻¹, in the case that an electric field of 1×10⁶ V/cm is applied to the light-emitting layer. The hole mobility is measured by means of TIME OF FLIGHT METHOD.

Furthermore, preferably, the lowest triplet excitation level (T1) of at least one of the at least two host materials is higher than T1 of the phosphorescent material.

The two host materials used in the invention can be used by selecting a combination that satisfies the above-mentioned conditions from materials described in a hole transporting host below.

<<Hole Transporting Host>>

The hole transporting host used for the organic layer of the present invention preferably has an ionization potential Ip of from 5.1 eV to 6.3 eV, more preferably has an ionization potential of from 5.4 eV to 6.1 eV, and even more preferably has an ionization potential of from 5.6 eV to 5.8 eV in view of improvements in durability and decrease in drive voltage. Furthermore, it preferably has an electron affinity Ea of from 1.2 eV to 3.1 eV, more preferably of from 1.4 eV to 3.0 eV, and even more preferably of from 1.8 eV to 2.8 eV in view of improvements in durability and decrease in drive voltage.

Specific examples of such hole transporting hosts as mentioned above include pyrrole, carbazole, azepine compound, carbene complex compound, triazole, oxazole, oxadiazole, pyrazole, imidazole, polyarylalkane, pyrazoline, pyrazolone, phenylenediamine, arylamine, amino-substituted chalcone, styrylanthracene, fluorenone, hydrazone, stilbene, silazane, aromatic tertiary amine compounds, styrylamine compounds, aromatic dimethylidine compounds, porphyrin compounds, polysilane compounds, poly(N-vinylcarbazole), aniline copolymers, electro-conductive high-molecular oligomers such as thiophene oligomers, polythiophenes and the like, organic silanes, carbon films, derivatives thereof, and the like.

Among these, it is preferred to select a carbazole compound as the first host material, and a carbazole compound, .an azepine compound or a carbene complex compound as the second host material.

As specific examples of the hole transporting hosts described above, the following compounds may be listed, but the present invention is not limited thereto.

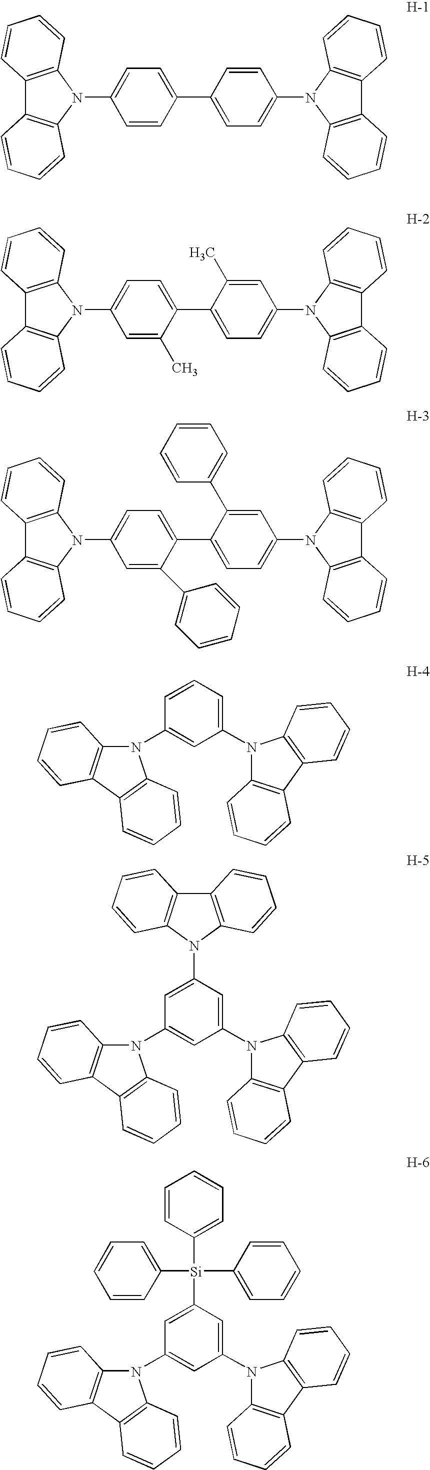

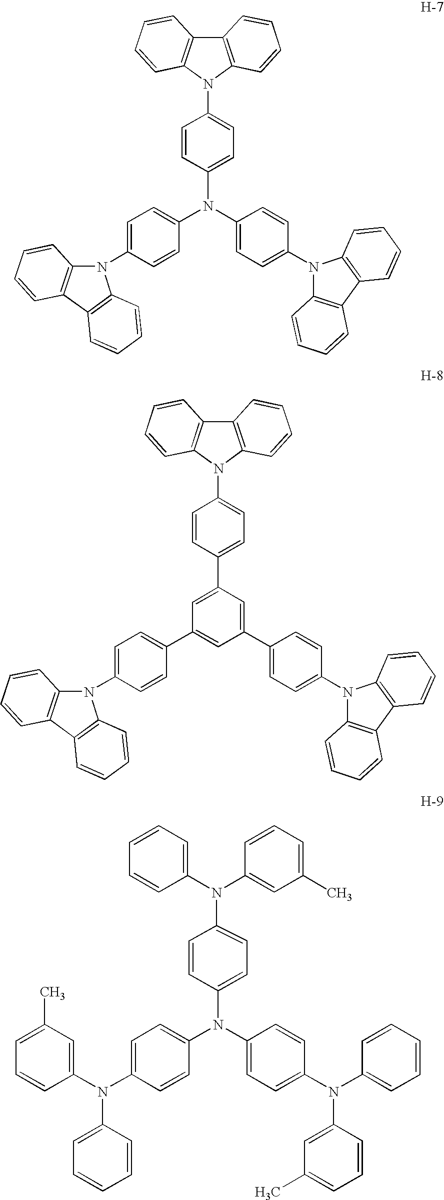

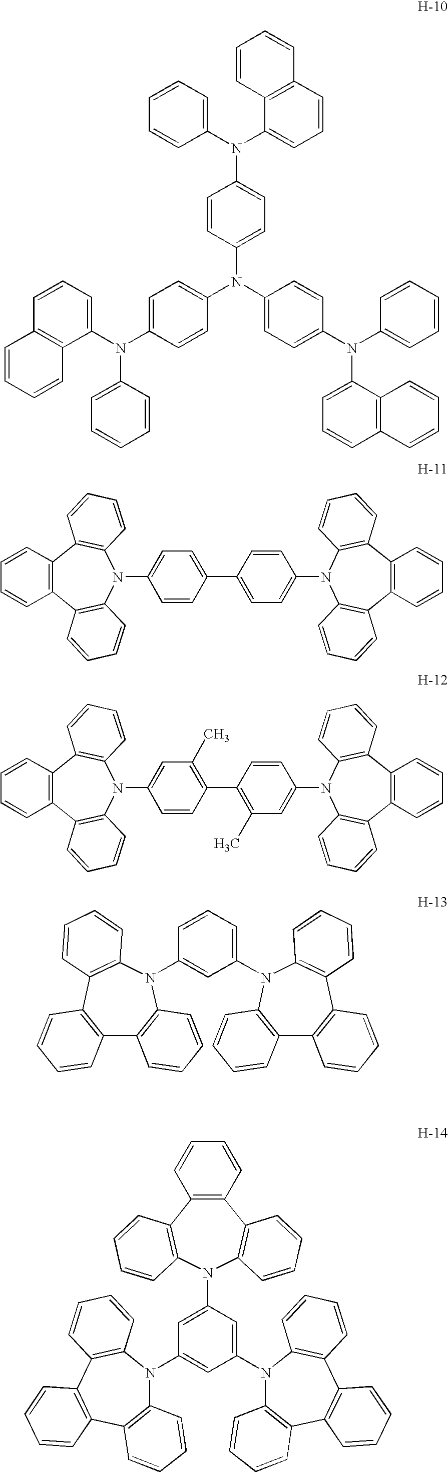

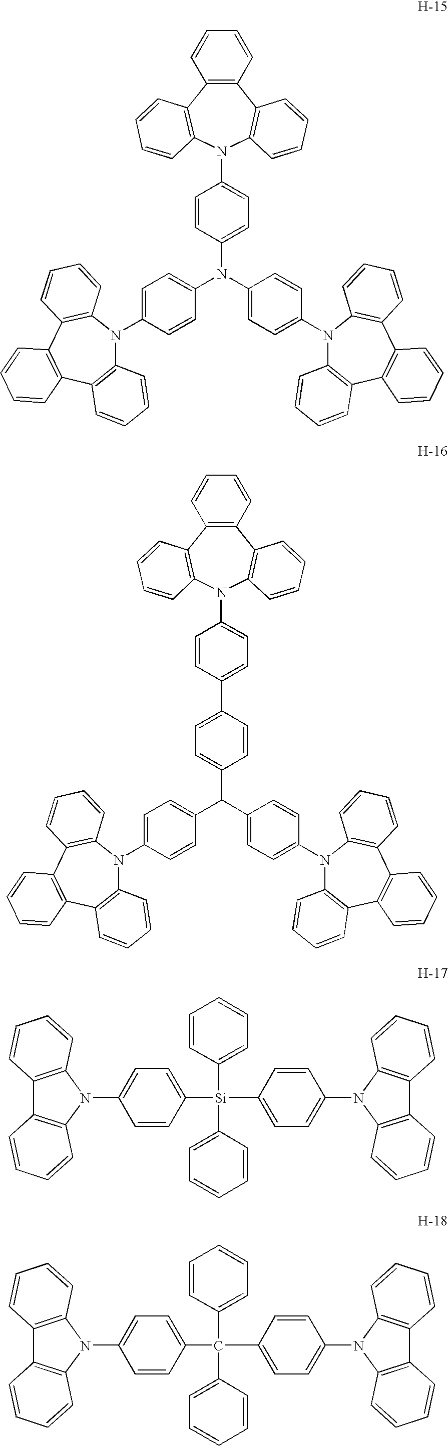

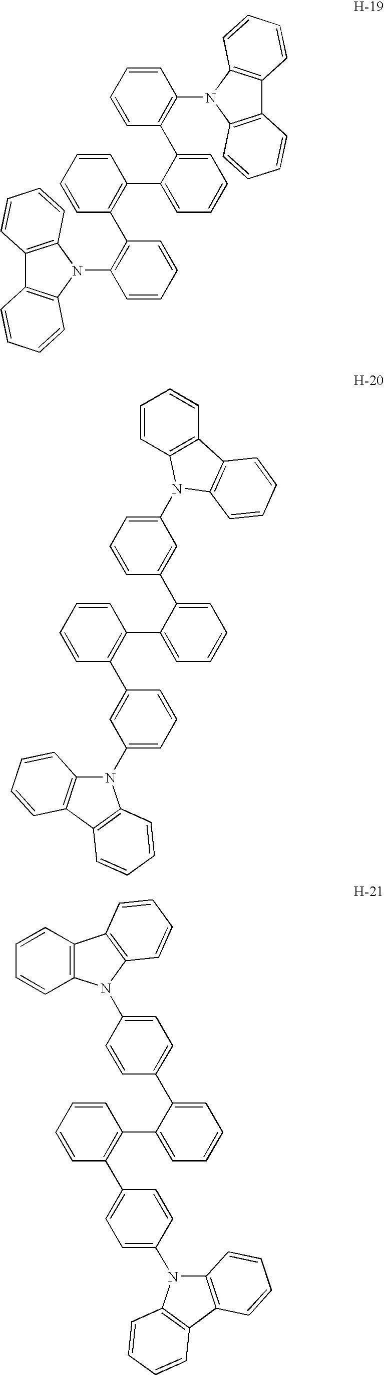

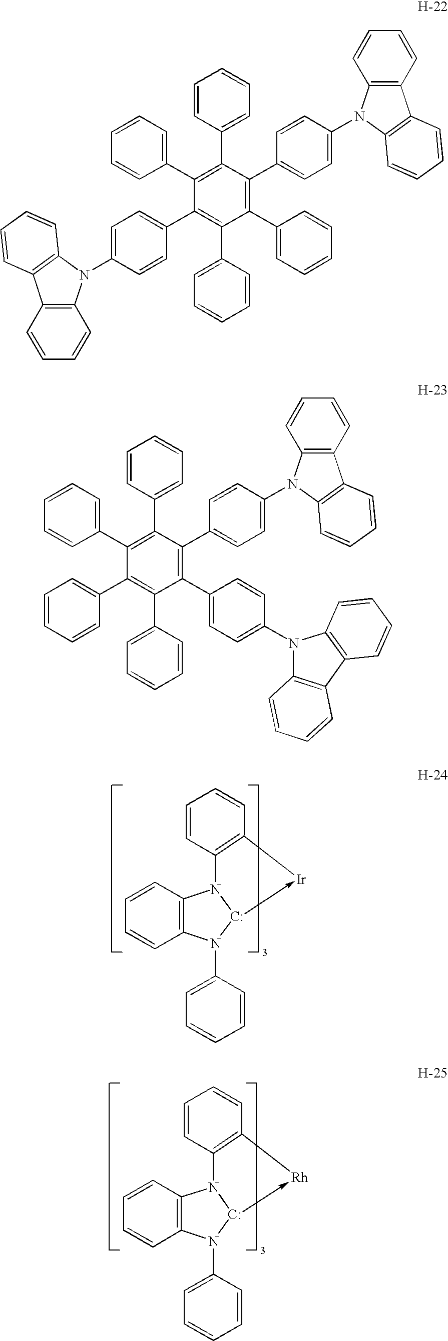

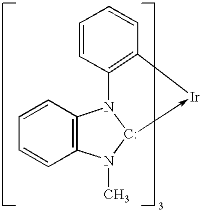

<<Electron Transporting Host>>

As the host material used in the present invention, an electron transporting host material (hereinafter sometimes referred as an “electron transporting host”), which is excellent in transporting electrons, may be contained in combination with a hole transporting host material, which is excellent in transporting holes.

As the electron transporting host used in the present invention, it is preferred that an electron affinity Ea of the host is from 2.5 eV to 3.5 eV, more preferably from 2.6 eV to 3.2 eV, and further preferably from 2.8 eV to 3.1 eV in view of improvements in durability and decrease in drive voltage. Furthermore, it is preferred that an ionization potential Ip of the host is from 5.7 eV to 7.5 eV, more preferably from 5.8 eV to 7.0 eV, and her preferably from 5.9 eV to 6.5 eV in view of improvements in durability and decrease in drive voltage.

Specific examples of such electron transporting hosts as mentioned above include pyridine, pyrimidine, triazine, imidazole, pyrazole, triazole, oxazole, oxadiazole, fluorenone, anthraquinonedimethane, anthrone, diphenylquinone, thiopyrandioxide, carbodiimide, fluorenylidenemethane, distyrylpyradine, fluorine-substituted aromatic compounds, heterocyclic tetracarboxylic anhydrides such as naphthaleneperylene and the like, phthalocyanine, derivatives thereof (which may form a condensed ring with another ring), and a variety of metal complexes represented by metal complexes of 8-quinolynol derivatives, metal phthalocyanine, and metal complexes having benzoxazole or benzothiazole as the ligand.

Preferable electron transporting hosts are metal complexes, azole derivatives (benzimidazole derivatives, imidazopyridine derivatives and the like), and azine derivatives (pyridine derivatives, pyrimidine derivatives, triazine derivatives and the like). Among these, metal complexes are preferred in the present invention in view of durability. As the metal complex compound, a metal complex containing a ligand having at least one nitrogen atom, oxygen atom, or sulfur atom to be coordinated with the metal is more preferable.

Although a metal ion in the metal complex is not particularly limited, a beryllium ion, a magnesium ion, an aluminum ion, a gallium ion, a zinc ion, an indium ion, a tin ion, a platinum ion, or a palladium ion is preferred; more preferable is a beryllium ion, an aluminum ion, a gallium ion, a zinc ion, a platinum ion, or a palladium ion; and further preferable is an aluminum ion, a zinc ion, or a palladium ion.

Although there are a variety of well-known ligands to be contained in the above-described metal complexes, examples thereof include ligands described in “Photochemistry and Photophysics of Coordination Compounds” authored by H. Yersin, published by Springer-Verlag Company in 1987; “YUHKI KINZOKU KAGAKU—KISO TO OUYOU—(Metalorganic Chemistry—Fundamental and Application—)” authored by Akio Yamamoto, published by Shokabo Publishing Co., Ltd. in 1982, and the like.

The ligands are preferably nitrogen-containing heterocyclic ligands (having preferably 1 to 30 carbon atoms, more preferably 2 to 20 carbon atoms, and particularly preferably 3 to 15 carbon atoms); and they may be a unidentate ligand or a bi- or higher-dentate ligand. Preferable are bi- to hexa-dentate ligands, and mixed ligands of bi- to hexa-dentate ligands with a unidentate ligand are also preferable.

Examples of the ligands include azine ligands (e.g. pyridine ligands, bipyridyl ligands, terpyridine ligands and the like); hydroxyphenylazole ligands (e.g. hydroxyphenylbenzimidazole ligands, hydroxyphenylbenzoxazole ligands, hydroxyphenylimidazole ligands, hydroxyphenylimidazopyridine ligands and the like); alkoxy ligands (those having preferably 1 to 30 carbon atoms, more preferably 1 to 20 carbon atoms, and particularly preferably 1 to 10 carbon atoms, examples of which include methoxy, ethoxy, butoxy, 2-ethylhexyloxy and the like); aryloxy ligands (those having preferably 6 to 30 carbon atoms, more preferably 6 to 20 carbon atoms, and particularly preferably 6 to 12 carbon atoms, examples of which include phenyloxy, 1-naphthyloxy, 2-naphthyloxy, 2,4,6-trimethylphenyloxy, 4-biphenyloxy and the like); heteroaryloxy ligands (those having preferably 1 to 30 carbon atoms, more preferably 1 to 20 carbon atoms, and particularly preferably 1 to 12 carbon atoms, examples of which include pyridyloxy, pyrazyloxy, pyriridyloxy, quinolyloxy and the like); alkylthio ligands (those having preferably 1 to 30 carbon atoms, more preferably 1 to 20 carbon atoms, and particularly preferably 1 to 12 carbon atoms, examples of which include methylthio, ethylthio and the like); arylthio ligands (those having preferably 6 to 30 carbon atoms, more preferably 6 to 20 carbon atoms, and particularly preferably 6 to 12 carbon atoms, examples of which include phenylthio and the like); heteroarylthio ligands (those having preferably 1 to 30 carbon atoms, more preferably 1 to 20 carbon atoms, and particularly preferably 1 to 12 carbon atoms, examples of which include pyridylthio, 2-benzimidazolylthio, benzooxazolylthio, 2-benzothiazolylthio and the like); siloxy ligands (those having preferably 1 to 30 carbon atoms, more preferably 3 to 25 carbon atoms, and particularly preferably 6 to 20 carbon atoms, examples of which include a triphenylsiloxy group, a triethoxysiloxy group, a triisopropylsiloxy group and the like); aromatic hydrocarbon anion ligands (those having preferably 6 to 30 carbon atoms, more preferably 6 to 25 carbon atoms, and particularly preferably 6 to 20 carbon atoms, examples of which include a phenyl anion, a naphthyl anion, an anthranyl anion and the like anion); aromatic heterocyclic anion ligands (those having preferably 1 to 30 carbon atoms, more preferably 2 to 25 carbon atoms, and particularly preferably 2 to 20 carbon atoms, examples of which include a pyrrole anion, a pyrazole anion, a triazole anion, an oxazole anion, a benzoxazole anion, a thiazole anion, a benzothiazole anion, a thiophene anion, a benzothiophene anion and the like); indolenine anion ligands and the like. Among these, nitrogen-containing heterocyclic ligands, aryloxy ligands, heteroaryloxy groups, aromatic hydrocarbon anion ligands, aromatic heterocyclic anion ligands or siloxy ligands are preferable, and nitrogen-containing heterocyclic ligands, aryloxy ligands, siloxy ligands, aromatic hydrocarbon anion ligands, or aromatic heterocyclic anion ligands are more preferable.

Examples of the metal complex electron transporting hosts include compounds described, for example, in JP-A Nos. 2002-235076, 2004-214179, 2004-221062, 2004-221065, 2004-221068, 2004-327313 and the like.

Specific examples of these electron transporting hosts include the following materials, but it should be noted that the present invention is not limited thereto.

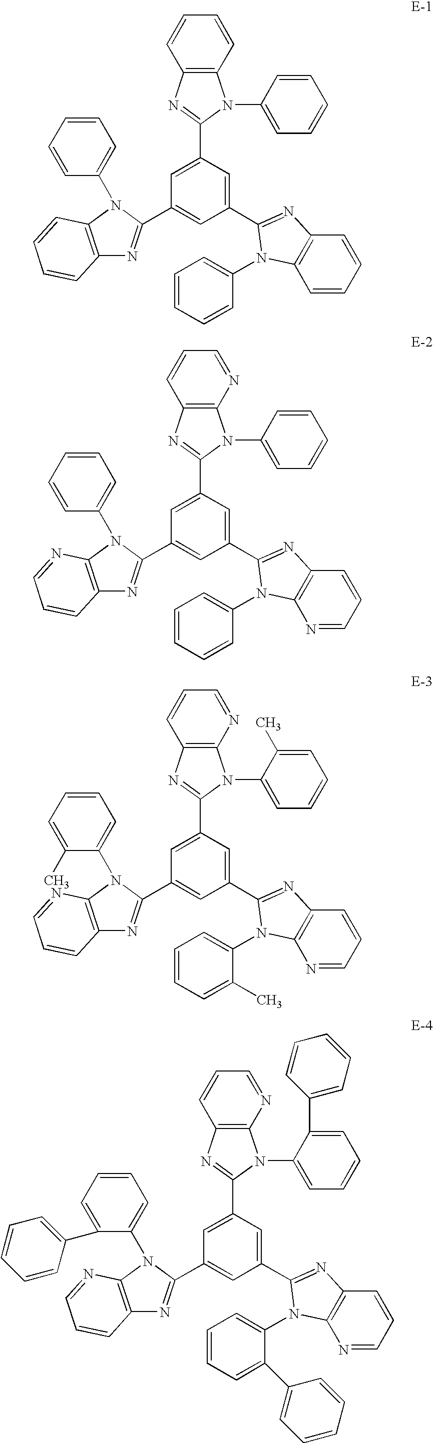

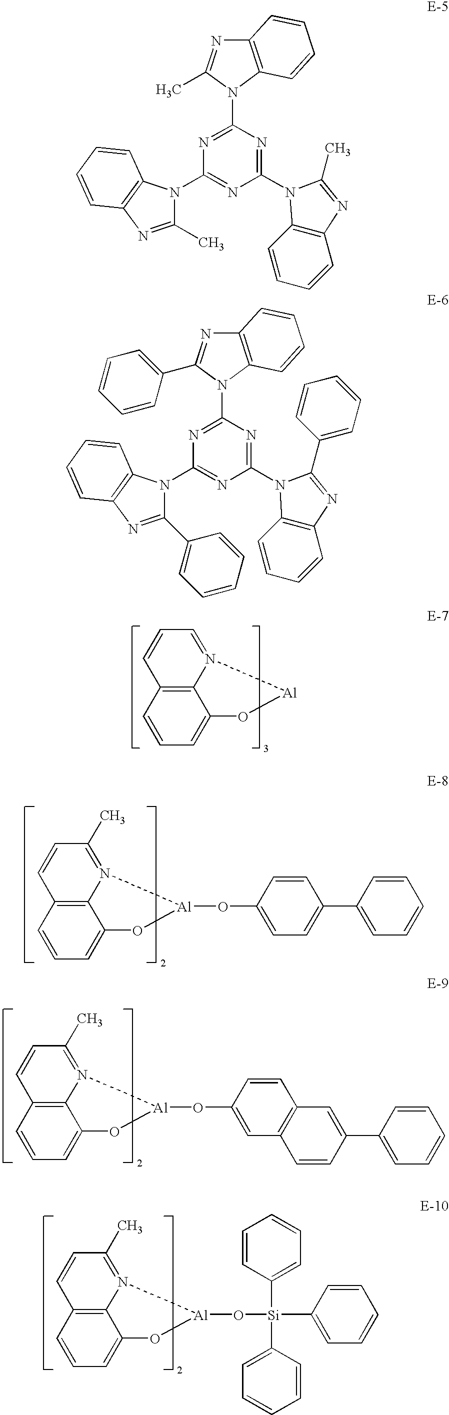

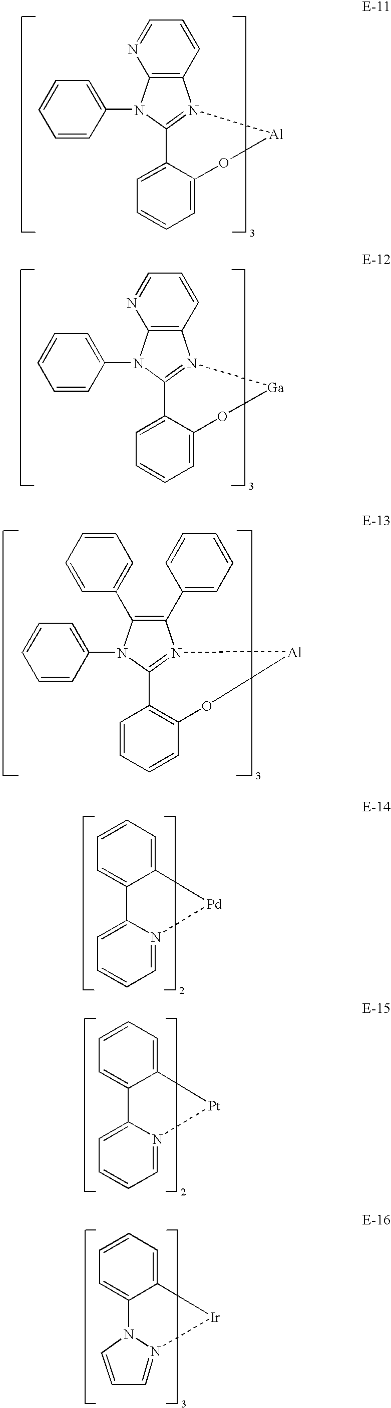

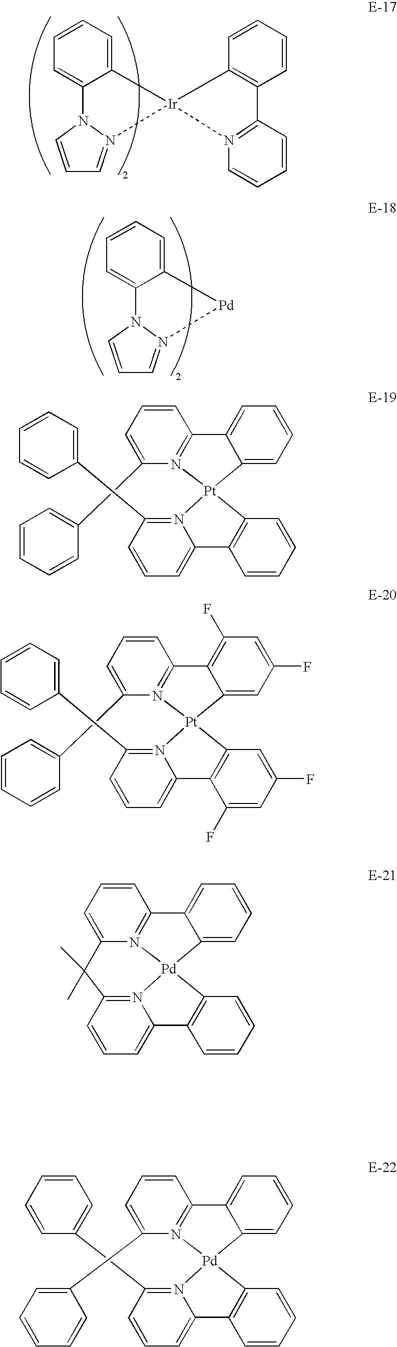

As the electron transport hosts, E-1 to E-6, E-8, E-9, E-10, E-21, or E-22 is preferred, E-3, E-4, E-6, E-8, E-9, E-10, E-21, or E-22 is more preferred, and E-3, E-4, E-21, or E-22 is even more preferred.

In the light-emitting layer of the present invention, it is preferred that the lowest triplet excitation level (T1) of at least one of the two host materials is higher than T1 of the phosphorescent material in view of color purity, light-emission efficiency, and drive durability.

Although a content of the host compounds according to the present invention is not particularly limited, it is preferably 15% by weight to 95% by weight with respect to the total mass of the compounds forming the light-emitting layer in view of luminescence efficiency and drive voltage.

(Hole Injection Layer and Hole Transport Layer)

The hole injection layer and the hole transport layer correspond to layers functioning to receive holes from an anode or from an anode side and to transport the holes to a cathode side.

As an electron-accepting dopant to be introduced into a hole injection layer or a hole transport layer, either of an inorganic compound or an organic compound may be used as long as the compound has electron accepting property and a function for oxidizing an organic compound. Specifically, Lewis acid compounds such as iron (III) chloride, aluminum chloride, gallium chloride, indium chloride, and antimony pentachloride are preferably used as the inorganic compounds.

In case of the organic compounds, compounds having substituents such as a nitro group, halogen, a cyano group, or a trifluoromethyl group; quinone compounds, acid anhydride compounds, and fullerenes may be preferably applied.

Specific examples of the organic compounds include hexacyanobutadiene, hexacyanobenzene, tetracyanoethylene, tetracyanoquinodimethane, tetrafluorotetracyanoquinodimethane, p-fluoranil, p-chloranil, p-bromanil, p-benzoquinone, 2,6-dichlorobenzoquinone, 2,5-dichlorobenzoquinone, tetramethylbenzoquinone, 1,2,4,5-tetracyanobenzene, o-dicyanobenzene, p-dicyanobenzene, 1,4-dicyanotetrafluorobenzene, 2,3-dichloro-5,6-dicyanobenzoquinone, p-dinitrobenzene, m-dinitrobenzene, o-dinitrobenzene, p-cyanonitrobenzene, m-cyanonitrobenzene, o-cyanonitrobenzene, 1,4-naphthoquinone, 2,3-dichloronaphthoquinone, 1-nitronaphthalene, 2-nitronaphthalene, 1,3-dinitronaphthalene, 1,5-dinitronaphthalene, 9-cyanoanthoracene, 9-nitroanthracene, 9,10-anthraquinone, 1,3,6,8-tetranitrocarbazole, 2,4,7-trinitro-9-fluorenone, 2,3,5,6-tetracyanopyridine, maleic anhydride, phthalic anhydride, fullerene C60, and fullerene C70.

Among these, hexacyanobutadiene, hexacyanobenzene, tetracyanoethylene, tetracyanoquinodimethane, tetrafluorotetracyanoquinodimethane, p-fluoranil, p-chloranil, p-bromanil, p-benzoquinone, 2,6-dichlorobenzoquinone, 2,5-dichlorobenzoquinone, 1,2,4,5-tetracyanobenzene, 1,4-dicyanotetrafluorobenzene, 2,3-dichloro-5,6-dicyanobenzoquinone, p-dinitrobenzene, m-dinitrobenzene, o-dinitrobenzene, 1,4-naphthoquinone, 2,3-dichloronaphthoquinone, 1,3-dinitronaphthalene, 1,5-dinitronaphthalene, 9,10-anthraquinone, 1,3,6,8-tetranitrocarbazole, 2,4,7-trinitro-9-fluorenone, 2,3,5,6-tetracyanopyridine, or fullerene C60 is preferable. Hexacyanobutadiene, hexacyanobenzene, tetracyanoethylene, tetracyanoquinodimethane, tetrafluorotetracyanoquinodimethane, p-fluoranil, p-chloranil, p-bromanil, 2,6-dichlorobenzoquinone, 2,5-dichlorobenzoquinone, 2,3-dichloronaphthoquinone, 1,2,4,5-tetracyanobenzene, 2,3-dichloro-5,6-dicyanobenzoquinone, or 2,3,5,6-tetracyanopyridine is particularly preferred.

These electron-accepting dopants may be used alone or in a combination of two or more of them.

Although an applied amount of these electron-accepting dopants depends on the type of material, 0.01% by weight to 50% by weight of a dopant is preferred with respect to a hole transport layer material, 0.05% by weight to 20% by weight is more preferable, and 0.1% by weight to 10% by weight is particularly preferred. When the amount applied is less than 0.01% by weight with respect to the hole injection material, it is not desirable because the advantageous effects of the present invention are insufficient, and when it exceeds 50% by weight, hole injection ability is deteriorated, and thus, this is not preferred.

In the case that the hole injection layer includes an acceptor, it is preferred that the hole transport layer substantially does not include an acceptor.

As a material for the hole injection layer and the hole transport layer, it is preferred to contain specifically pyrrole derivatives, carbazole derivatives, pyrazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidine compounds, porphyrin compounds, organosilane derivatives, carbon or the like.

Although a thickness of the hole injection layer and the hole transport layer is not particularly limited, it is preferred that the thickness is 1 nm to 5 μm, it is more preferably 5 nm to 1 μm, and 10 nm to 500 nm is particularly preferred in view of decrease in drive voltage, improvements in light-emission efficiency, and improvements in durability.

The hole injection layer and the hole transport layer may have a monolayered structure comprising one or two or more of the above-mentioned materials, or a multilayer structure composed of plural layers of a homogeneous composition or heterogeneous compositions.

A carrier mobility in the hole transport layer is usually from 10⁻⁷ cm²·V⁻¹·s⁻¹ to 10⁻¹ cm²·V⁻¹·s⁻¹; and in this range, from 10⁻⁵ cm²·V⁻¹·s⁻¹ to 10⁻¹ cm²·V⁻¹·s⁻¹ is preferable; from 10⁻⁴ cm²·V⁻¹·s⁻¹ to 10⁻¹ cm²·V⁻¹·s⁻¹ is more preferable; and from 10⁻³ cm²·V⁻¹·s⁻¹ to 10⁻¹ cm²·V⁻¹·s⁻¹ is particularly preferable in view of the light-emission efficiency.

For the carrier mobility, a value measured in accordance with the same method as that of the carrier mobility of the above-described light-emitting layer is adopted.

(Electron Injection Layer and Electron-Transport Layer)

The electron injection layer and the electron-transport layer are layers having any of functions for injecting electrons from the cathode, transporting electrons, and becoming a barrier to holes which could be injected from the anode.

As a material applied for the electron-donating dopant with respect to the electron injection layer or the electron-transport layer, any material may be used as long as it has an electron-donating property and a property for reducing an organic compound, and alkaline metals such as Li, alkaline earth metals such as Mg, and transition metals including rare-earth metals are preferably used.

Particularly, metals having a work function of 4.2 V or less are preferably applied, and specific examples thereof include Li, Na, K, Be, Mg, Ca, Sr, Ba, Y, Cs, La, Sm, Gd, and Yb.

These electron-donating dopants may be used alone or in a combination of two or more of them.

An applied amount of the electron-donating dopants differs dependent on the types of the materials, but it is preferably 0.1% by weight to 99% by weight with respect to an electron-transport layer material, more preferably 1.0% by weight to 80% by weight, and particularly preferably 2.0% by weight to 70% by weight. When the amount applied is less than 0.1% by weight with respect to the electron transport material, the efficiency of the present invention is not sufficiently realized so that it is not desirable, and when it exceeds 99% by weight, the electron transportation ability is deteriorated so that it is not preferred.

Specific examples of the materials applied for the electron injection layer and the electron-transport layer include pyridine, pyrimidine, triazine, imidazole, triazole, oxazole, oxadiazole, fluorenone, anthraquinodimethane, anthrone, diphenylquinone, thiopyrandioxide, carbodiimide, fluorenylidenemethane, distyrylpyradine, fluorine-substituted aromatic compounds, naphthalene, heterocyclic tetracarboxylic anhydrides such as perylene, phthalocyanine, and derivatives thereof (which may form condensed rings with the other rings); and metal complexes represented by metal complexes of 8-quinolinol derivatives, metal phthalocyanine, and metal complexes containing benzoxazole, or benzothiazole as the ligand.

Although a thickness of the electron injection layer and the electron-transport layer is not particularly limited, it is preferred that the thickness is in 1 nm to 5 μm, it is more preferably 5 nm to 1 μm, and it is particularly preferably 10 nm to 500 nm in view of decrease in drive voltage, improvements in light-emission efficiency, and improvements in durability.

The electron injection layer and the electron-transport layer may have either a mono-layered structure comprising one or two or more of the above-mentioned materials, or a multilayer structure composed of plural layers of a homogeneous composition or a heterogeneous composition.

Furthermore, the carrier mobility in the electron-transport layer is usually from 10⁻⁷ cm²·V⁻¹·s⁻¹ to 10⁻¹ cm²·V⁻¹·s⁻¹, and in this range, from 10⁻⁵ cm²·V⁻¹·s⁻¹ to 10⁻¹ cm²·V⁻¹·s⁻¹ is preferable, from 10⁻⁴ cm²·V⁻¹·s⁻¹ to 10⁻¹ cm²·V⁻¹·s⁻¹ is more preferable, and from 10⁻³ cm²·V⁻¹·s⁻¹ to 10⁻¹ cm²·V⁻¹·s⁻¹ is particularly preferred, in view of light-emission efficiency.

(Hole-Blocking Layer)

A hole-blocking layer is a layer having a function to prevent the holes transported from the anode to the light-emitting layer from passing through to the cathode side. According to the present invention, a hole-blocking layer may be provided as an organic compound layer adjacent to the light-emitting layer on the cathode side.

The hole-blocking layer is not particularly limited, but specifically, it may contain an aluminum complex such as BAlq, a triazole derivative, a pyrazabol derivative or the like.

It is preferred that a thickness of the hole-blocking layer is generally 50 nm or less in order to decrease the drive voltage, more preferably it is from 1 nm to 50 nm, and even more preferably it is from 5 nm to 40 nm.

(Anode)

The anode may generally be any material as long as it has a function as an electrode for supplying holes to the organic compound layer, and there is no particular limitation as to the shape, the structure, the size or the like. However, it may be suitably selected from among well-known electrode materials according to the application and purpose of luminescence device. As mentioned above, the anode is usually provided as a transparent anode.

Materials for the anode may preferably include, for example, metals, alloys, metal oxides, electro-conductive compounds, and mixtures thereof, and those having a work function of 4.0 eV or more are preferred. Specific examples of the anode materials include electro-conductive metal oxides such as tin oxides doped with antimony, fluorine or the like (ATO and FTO), tin oxide, zinc oxide, indium oxide, indium tin oxide (ITO), and indium zinc oxide (IZO); metals such as gold, silver, chromium, and nickel; mixtures or laminates of these metals and the electro-conductive metal oxides; inorganic electro-conductive materials such as copper iodide and copper sulfide; organic electro-conductive materials such as polyaniline, polythiophene, and polypyrrole; and laminates of these inorganic or organic electron-conductive materials with ITO. Among these, the electro-conductive metal oxides are preferred, and particularly, ITO is preferable in view of productivity, high electro-conductivity, transparency and the like.

The anode may be formed on the substrate in accordance with a method which is appropriately selected from among wet methods such as printing methods, coating methods and the like; physical methods such as vacuum deposition methods, sputtering methods, ion plating methods and the like; and chemical methods such as CVD and plasma CVD methods and the like, in consideration of the suitability to a material constituting the anode. For instance, when ITO is selected as a material for the anode, the anode may be formed in accordance with a DC or high-frequency sputtering method, a vacuum deposition method, an ion plating method or the like.

In the organic electroluminescence device of the present invention, a position at which the anode is to be formed is not particularly limited, but it may be suitably selected according to the application and purpose of the luminescence device. The anode may be formed on either the whole surface or a part of the surface on either side of the substrate.

For patterning to form the anode, a chemical etching method such as photolithography, a physical etching method such as etching by laser, a method of vacuum deposition or sputtering through superposing masks, or a lift-off method or a printing method may be applied.

A thickness of the anode may be suitably selected according to the material constituting the anode and is therefore not definitely decided, but it is usually in the range of around 10 nm to 50 μm, and preferably 50 nm to 20 μm.

A value of resistance of the anode is preferably 10³ Ω/□ or less, and 10² Ω/□ or less is more preferable. In the case where the anode is transparent, it may be either transparent and colorless, or transparent and colored. For extracting luminescence from the transparent anode side, it is preferred that a light transmittance of the anode is 60% or higher, and more preferably 70% or higher.

Concerning transparent anodes, there is a detailed description in “TOUMEI DENNKYOKU-MAKU NO SHINTENKAI (Novel Developments in Transparent Electrode Films)” edited by Yutaka Sawada, published by C.M.C. in 1999, the contents of which are incorporated by reference herein. In the case where a plastic substrate having a low heat resistance is applied, it is preferred that ITO or IZO is used to obtain a transparent anode prepared by forming the film at a low temperature of 150° C. or lower.

(Cathode)

The cathode may generally be any material as long as it has a function as an electrode for injecting electrons to the organic compound layer, and there is no particular limitation as to the shape, the structure, the size or the like. However it may be suitably selected from among well-known electrode materials according to the application and purpose of the luminescence device.

Materials constituting the cathode may include, for example, metals, alloys, metal oxides, electro-conductive compounds, and mixtures thereof, and materials having a work function of 4.5 eV or less are preferred. Specific examples thereof include alkali metals (e.g., Li, Na, K, Cs or the like), alkaline earth metals (e.g., Mg, Ca or the like), gold, silver, lead, aluminum, sodium-potassium alloys, lithium-aluminum alloys, magnesium-silver alloys, rare earth metals such as indium, and ytterbium, and the like. They may be used alone, but it is preferred that two or more of them are used in combination from the viewpoint of satisfying both stability and electron inject ability.

Among these, as the materials for constituting the cathode, alkaline metals or alkaline earth metals are preferred in view of electron inject ability, and materials containing aluminum as a major component are preferred in view of excellent preservation stability.

The term “material containing aluminum as a major component” refers to a material constituted by aluminum alone; alloys comprising aluminum and 0.01% by weight to 10% by weight of an alkaline metal or an alkaline earth metal; or the mixtures thereof (e.g., lithium-aluminum alloys, magnesium-aluminum alloys and the like).

Regarding materials for the cathode, they are described in detail in JP-A Nos. 2-15595 and 5-121172, of which are incorporated by reference herein.

A method for forming the cathode is not particularly limited, but it may be formed in accordance with a well-known method.

For instance, the cathode may be formed in accordance with a method which is appropriately selected from among wet methods such as printing methods, coating methods and the like; physical methods such as vacuum deposition methods, sputtering methods, ion plating methods and the like; and chemical methods such as CVD and plasma CVD methods and the like, in consideration of the suitability to a material constituting the cathode. For example, when a metal (or metals) is (are) selected as a material (or materials) for the cathode, one or two or more of then may be applied at the same time or sequentially in accordance with a sputtering method or the like.

For patterning to form the cathode, a chemical etching method such as photolithography, a physical etching method such as etching by laser, a method of vacuum deposition or sputtering through superposing masks, or a lift-off method or a printing method may be applied.

In the present invention, a position at which the cathode is to be formed is not particularly limited, and it may be formed on either the whole or a part of the organic compound layer.

Furthermore, a dielectric material layer made of fluorides, oxides or the like of an alkaline metal or an alkaline earth metal may be inserted in between the cathode and the organic compound layer with a thickness of 0.1 nm to 5 nm. The dielectric layer may be considered to be a kind of electron injection layer. The dielectric material layer may be formed in accordance with, for example, a vacuum deposition method, a sputtering method, an ion-plating method or the like.

A thickness of the cathode may be suitably selected according to materials for constituting the cathode and is therefore not definitely decided, but it is usually in the range of around 10 nm to 5 μm, and preferably 50 nm to 1 μm.

Moreover, the cathode may be transparent or opaque. The transparent cathode may be formed by preparing a material for the cathode with a small thickness of 1 nm to 10 nm, and further laminating a transparent electro-conductive material such as ITO or IZO thereon.

(Substrate)

According to the present invention, a substrate may be applied. The substrate to be applied is preferably one which does not scatter or attenuate light emitted from the organic compound layer. Specific examples of materials for the substrate include zirconia-stabilized yttrium (YSZ); inorganic materials such as glass; polyesters such as polyethylene terephthalate, polybutylene phthalate, and polyethylene naphthalate; and organic materials such as polystyrene, polycarbonate, polyethersulfone, polyarylate, polyimide, polycycloolefin, norbornene resin, polychlorotrifluoroethylene, and the like.

For instance, when glass is used as the substrate, non-alkali glass is preferably used with respect to the quality of material in order to decrease ions eluted from the glass. In the case of employing soda-lime glass, it is preferred to use glass on which a barrier coat such as silica has been applied. In the case of employing an organic material, it is preferred to use a material excellent in heat resistance, dimension stability, solvent resistance, electrical insulation, and workability.

There is no particular limitation as to the shape, the structure, the size or the like of the substrate, but it may be suitably selected according to the application, purposes and the like of the luminescence device. In general, a plate-like substrate is preferred as the shape of the substrate. A structure of the substrate may be a monolayer structure or a laminated structure. Furthermore, the substrate may be formed from a single member or two or more members.

Although the substrate may be transparent and colorless, or transparent and colored, it is preferred that the substrate is transparent and colorless from the viewpoint that the substrate does not scatter or attenuate light emitted from the organic light-emitting layer.

A moisture permeation preventive layer (gas barrier layer) may be provided on the front surface or the back surface of the substrate.

For a material of the moisture permeation preventive layer (gas barrier layer), inorganic substances such as silicon nitride and silicon oxide may be preferably applied. The moisture permeation preventive layer (gas barrier layer) may be formed in accordance with, for example, a high-frequency sputtering method or the like.

In the case of applying a thermoplastic substrate, a hard-coat layer or an under-coat layer may be further provided as needed.

(Protective Layer)

According to the present invention, the whole organic EL device may be protected by a protective layer.

A material contained in the protective layer may be one having a function to prevent penetration of substances such as moisture and oxygen, which accelerate deterioration of the device, into the device.

Specific examples thereof include metals such as In, Sn, Pb, Au, Cu, Ag, Al, Ti, Ni and the like; metal oxides such as MgO, SiO, SiO₂, Al₂O₃, GeO, NiO, CaO, BaO, Fe₂O₃, Y₂O₃, TiO₂ and the like; metal nitrides such as SiNₓ, SiNₓO_{y} and the like; metal fluorides such as MgF₂, LiF, AlF₃, CaF₂ and the like; polyethylene; polypropylene; polymethyl methacrylate; polyimide; polyurea; polytetrafluoroethylene; polychlorotrifluoroethylene; polydichlorodifluoroethylene; a copolymer of chlorotrifluoroethylene and dichlorodifluoroethylene; copolymers obtained by copolymerizing a monomer mixture containing tetrafluoroethylene and at least one co-monomer; fluorine-containing copolymers each having a cyclic structure in the copolymerization main chain; water-absorbing materials each having a coefficient of water absorption of 1% or more; moisture permeation preventive substances each having a coefficient of water absorption of 0.1% or less; and the like.

There is no particular limitation as to a method for forming the protective layer. For instance, a vacuum deposition method, a sputtering method, a reactive sputtering method, an MBE (molecular beam epitaxial) method, a cluster ion beam method, an ion plating method, a plasma polymerization method (high-frequency excitation ion plating method), a plasma CVD method, a laser CVD method, a thermal CVD method, a gas source CVD method, a coating method, a printing method, or a transfer method may be applied.

(Sealing)

The whole organic electroluminescence device of the present invention may be sealed with a sealing cap.

Furthermore, a moisture absorbent or an inert liquid may be sealed between the sealing cap and the luminescence device. Although the moisture absorbent is not particularly limited, specific examples thereof include barium oxide, sodium oxide, potassium oxide, calcium oxide, sodium sulfate, calcium sulfate, magnesium sulfate, phosphorus pentoxide, calcium chloride, magnesium chloride, copper chloride, cesium fluoride, niobium fluoride, calcium bromide, vanadium bromide, molecular sieve, zeolite, magnesium oxide and the like. Although the inert liquid is not particularly limited, specific examples thereof include paraffins; liquid paraffins; fluorocarbon solvents such as perfluoroalkanes, perfluoroamines, perfluoroethers and the like; chlorine-based solvents; silicone oils; and the like.

In the organic electroluminescence device of the present invention, when a DC (AC components may be contained as needed) voltage (usually 2 volts to 15 volts) or DC is applied across the anode and the cathode, luminescence can be obtained.

The drive durability of the organic electroluminescence device according to the present invention can be determined based on a time at which the luminance is reduced to a specified value at a specified luminance. For instance, the luminance reduction time may be determined by using a source measure unit, model 2400, manufactured by KEITHLEY to apply a DC voltage to the organic EL device to cause it to emit light, conducting a continuous driving test under the condition that the initial luminance is 500 cd/m², defining the time required for the luminance to reach 200 cd/m² as a luminance reduction time, and then comparing the resulting luminance reduction time with that of a conventional luminescence device. According to the present invention, the numerical value thus obtained was used.

An important characteristic parameter of the organic electroluminescence device of the present invention is external quantum efficiency. The external quantum efficiency is calculated by “the external quantum efficiency (φ)=the number of photons emitted from the device/the number of electrons injected to the device”, and it may be said that the larger the value obtained is, the more advantageous the device is in view of electric power consumption.

Moreover, the external quantum efficiency of the organic electroluminescence device is decided by “the external quantum efficiency (φ)=the internal quantum efficiency×light-extraction efficiency”. In an organic EL device which utilizes the fluorescent luminescence from the organic compound, an upper limit of the internal quantum efficiency is 25%, while the light-extraction efficiency is about 20%, and accordingly, it is considered that an upper limit of the external quantum efficiency is about 5%.

As the numerical value of the external quantum efficiency, the maximum value thereof when the device is driven at 20° C., or a value of the external quantum efficiency at about 100 cd/m² to 300 cd/m² (preferably 200 cd/m²) when the device is driven at 20° C. may be used.

According to the present invention, a value obtained by the following method is used. Namely, a DC constant voltage is applied to the EL device by the use of a source measure unit, model 2400, manufactured by Toyo TECHNICA Corporation to cause it to emit light, the luminance of the light is measured by using a luminance photometer (trade name: BM-8, manufactured by Topeon Corporation), and then, the external quantum efficiency at 200 cd/m² is calculated.

Further, an external quantum efficiency of the luminescence device may be obtained by measuring the light-emitting luminance the luminescent spectrum, and the current density, and calculating the external quantum efficiency from these results and a specific visibility curve. In other words, using the current density value, the number of electrons injected can be calculated. By an integration calculation using the luminescent spectrum and the specific visibility curve (spectrum), the luminance can be converted into the number of photons emitted. From the result, the external quantum efficiency (%) can be calculated by “(the number of photons emitted/the number of electrons injected to the device)×100”.

For the driving method of the organic electroluminescence device of the present invention, driving methods described in JP-A Nos. 2-148687, 6-301355, 5-29080, 7-134558, 8-234685, and 8-241047; Japanese Patent No. 2784615, U.S. Pat. Nos. 5,828,429 and 6,023,308 are applicable.

(Application of the Organic Electroluminescence Device of the Present Invention)

The organic electroluminescence device of the present invention can be appropriately used for indicating elements, displays, backlights, electronic photographs, illumination light sources, recording light sources, exposure light sources, reading light sources, signages, advertising displays, interior accessories, optical communications and the like.

All publications, patent applications, and technical standards mentioned in this specification are herein incorporated by reference to the same extent as if each individual publication, patent application, or technical standard was specifically and individually indicated to be incorporated by reference.

### EXAMPLES

In the following, the organic electroluminescence device of the present invention will be explained by examples thereof, but the invention is by no means limited by such examples.

### Examples 1 to 16

### 1. Preparation of Organic EL Device

A glass substrate having an evaporated layer of indium-tin oxide (which is referred to hereinafter as ITO in some cases) (manufactured by Geomatec Co., Ltd., surface resistance. 10 Ω/□, size: 0.5 mm in thickness and 2.5 cm square) was placed in a washing vessel, subjected to an ultrasonic washing in 2-propanol and subjected to a UV-ozone treatment for 30 minutes. On this transparent anode, following layers were vacuum evaporated in succession by a vacuum deposition method. In the examples of the invention, the evaporation rate is 0.2 nm/sec unless specified otherwise. The evaporation rate was measured with a crystal oscillator. Also film thicknesses described in the following were measured with a crystal oscillator.

Hole Injection Layer

4,4′,4″-tris(2-naphthylphenylamino)-triphenylamine (which is referred to hereinafter as 2-TNATA in some cases) was doped with 2,3,5,6-tetrafluoro-7,7,8,8-tetracyanoquinodimethane (which is referred to hereinafter as F4-TCNQ in some cases) in an amount of 1.0% by weight, and was evaporated with a film thickness of 140 nm.

Hole Transport Layer

On the hole injection layer, N,N′-dinaphthyl-N,N′-diphenyl-[1,1′-biphenyl]-4,4′-diamine (which is referred to hereinafter as α-NPD in some cases) was evaporated with a film thickness of 10 nm.

Hole Transport Intermediate Layer

On the hole transport layer, compound (A) was evaporated with a film thickness of 3 nm.

Light-Emitting Layer

With a compound (B) as a light-emitting material, various host materials were co-evaporated at a ratio of light-emitting material:total host material=15:85 by weight and at a thickness of 60 nm.

In Table 1, host materials used, the Ip values thereof, the hole mobilities thereof and the hole mobility of the light-emitting layer are shown together.

Electron Transport Layer

Aluminum (III) bis(2-methyl-8-quinolinate)-4-phenylphenolate (which is referred to hereinafter as Balq in some cases) was evaporated with a film thickness of 39 nm.

Electron Injection Layer

2,9-Dimethyl-4,7-diphenyl-1,10-phenanthroline (which is referred to hereinafter as BCP in some cases) was evaporated with a film thickness of 1 nm.

Cathode

A patterned mask (providing a light emission area of 2 mm×2 mm) was disposed thereon, then lithium fluoride (LiF) was evaporated with a thickness of 0.5 nm and aluminum metal was evaporated with a thickness of 100 nm to form a cathode.

The laminate member thus produced was placed in a glove box substituted with argon gas, and was sealed utilizing a stainless steel sealing container and an ultraviolet-curable adhesive (XNR5516HV, manufactured by Nagase-Ciba Co., Ltd.).

TABLE 1

| | First Host Material | | | Second Host Material | | | | ΔIp | Hole Mobility of |
|---|---|---|---|---|---|---|---|---|---|
| | | Ip(1) | M(1) | | | | Mixing Ratio | (Ip(2) − | Light-emitting Layer |
| Device No. | Compound | (eV) | (cm² · V⁻¹ · sec⁻¹) | Compound | Ip(2) | M(2) | (% by weight) | Ip(1)) | (cm² · V⁻¹ · sec⁻¹) |
| Comparative 1 | mCP | 6.1 | 1.8 × 10⁻³ | — | — | — | 0 | — | 1.2 × 10⁻³ |
| Comparative 2 | mCP | 6.1 | 1.8 × 10⁻³ | Compound A | 5.8 | 4.2 × 10⁻⁴ | 25 | 0.3 | 4.3 × 10⁻⁴ |
| Comparative 3 | mCP | 6.1 | 1.8 × 10⁻³ | Compound A | 5.8 | 4.2 × 10⁻⁴ | 40 | 0.3 | 9.4 × 10⁻⁴ |
| Invention 1 | mCP | 6.1 | 1.8 × 10⁻³ | Compound A | 5.8 | 4.2 × 10⁻⁴ | 20 | 0.3 | 2.5 × 10⁻⁵ |
| Invention 2 | mCP | 6.1 | 1.8 × 10⁻³ | Compound A | 5.8 | 4.2 × 10⁻⁴ | 5 | 0.3 | 1.2 × 10⁻⁵ |
| Invention 3 | mCP | 6.1 | 1.8 × 10⁻³ | Compound A | 5.8 | 4.2 × 10⁻⁴ | 10 | 0.3 | 8.5 × 10⁻⁵ |
| Invention 4 | mCP | 6.1 | 1.8 × 10⁻³ | Compound C | 5.7 | 8.5 × 10⁻⁴ | 20 | 0.4 | 4.2 × 10⁻⁵ |
| Invention 5 | mCP | 6.1 | 1.8 × 10⁻³ | Compound C | 5.7 | 8.5 × 10⁻⁴ | 5 | 0.4 | 5.1 × 10⁻⁵ |
| Invention 6 | mCP | 6.1 | 1.8 × 10⁻³ | Compound D | 5.9 | 2.3 × 10⁻⁶ | 20 | 0.2 | 5.7 × 10⁻⁵ |
| Invention 7 | mCP | 6.1 | 1.8 × 10⁻³ | Compound D | 5.9 | 2.3 × 10⁻⁶ | 5 | 0.2 | 6.8 × 10⁻⁵ |
| Invention 8 | Compound F | 6.0 | 8.8 × 10⁻⁴ | Compound A | 5.8 | 4.2 × 10⁻⁴ | 20 | 0.2 | 2.8 × 10⁻⁶ |
| Invention 9 | Compound F | 6.0 | 8.8 × 10⁻⁴ | Compound A | 5.8 | 4.2 × 10⁻⁴ | 5 | 0.2 | 3.4 × 10⁻⁶ |
| Invention 10 | mCP | 6.1 | 1.8 × 10⁻³ | Compound G | 5.5 | 7.1 × 10⁻⁵ | 1 | 0.6 | 3.2 × 10⁻⁵ |
| Invention 11 | mCP | 6.1 | 1.8 × 10⁻³ | Compound G | 5.5 | 7.1 × 10⁻⁵ | 5 | 0.6 | 4.7 × 10⁻⁵ |
| Invention 12 | mCP | 6.1 | 1.8 × 10⁻³ | Compound G | 5.5 | 7.1 × 10⁻⁵ | 20 | 0.6 | 6.3 × 10⁻⁵ |
| Invention 13 | mCP | 6.1 | 1.8 × 10⁻³ | Compound E | 5.4 | 1.8 × 10⁻⁴ | 1 | 0.7 | 8.7 × 10⁻⁶ |
| Invention 14 | mCP | 6.1 | 1.8 × 10⁻³ | Compound E | 5.4 | 1.8 × 10⁻⁴ | 5 | 0.7 | 9.8 × 10⁻⁶ |
| Invention 15 | mCP | 6.1 | 1.8 × 10⁻³ | Compound E | 5.4 | 1.8 × 10⁻⁴ | 10 | 0.7 | 1.5 × 10⁻⁵ |
| Invention 16 | mCP | 6.1 | 1.8 × 10⁻³ | Compound E | 5.4 | 1.8 × 10⁻⁴ | 20 | 0.7 | 3.4 × 10⁻⁵ |

Structures of the compounds used in the above-described luminescence devices are shown below.

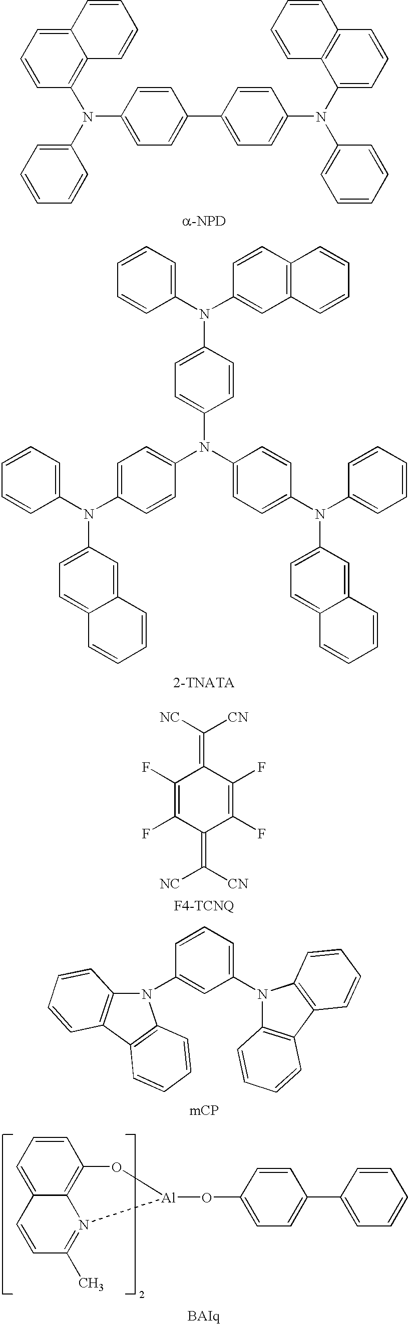

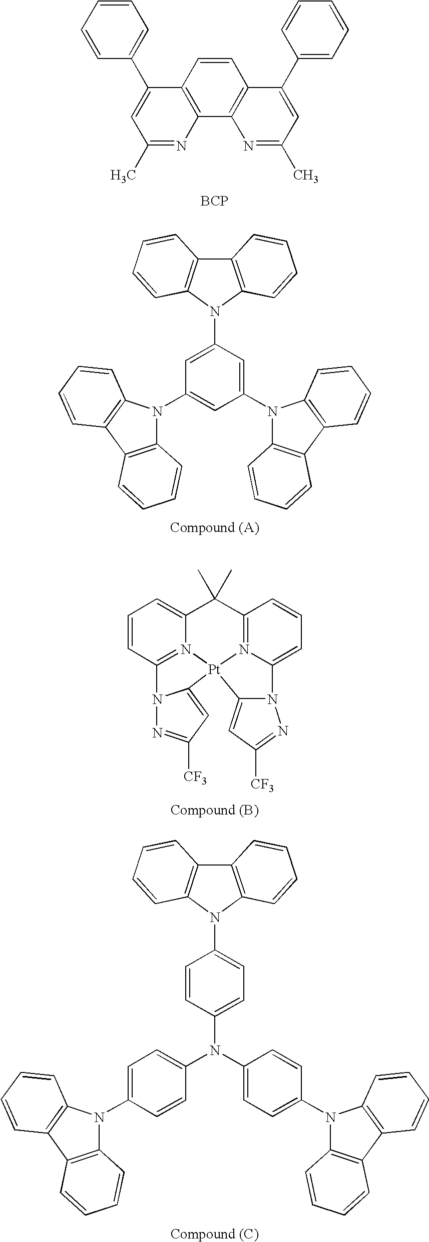

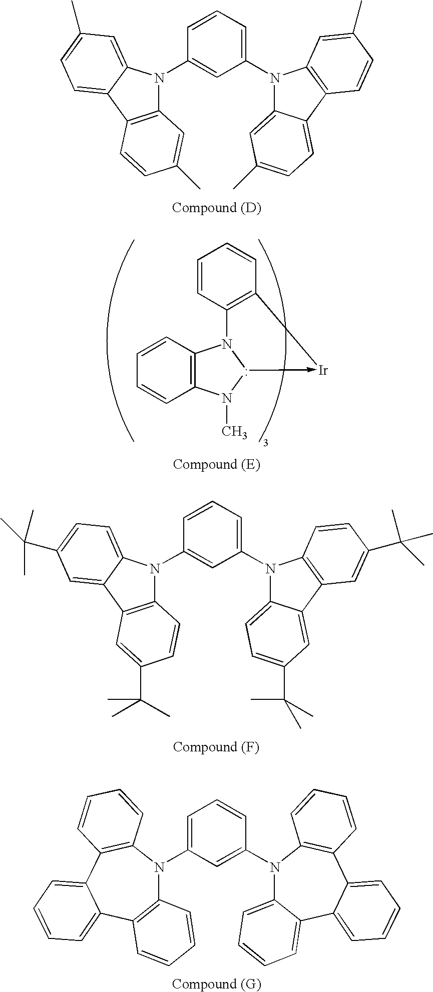

### 3. Evaluation of Performance

### (Evaluation Items)

(1) Light Emission Efficiency

An external quantum efficiency of the luminescence device was calculated from the results of measurements of a luminance, a light-emission spectrum and a current density, and a relative luminosity curve. The external quantum efficiency (%) was calculated by “(number of emitted photons/number of input electrons to the device)×100”.

(2) Drive Voltage

The drive voltage at an luminance of 360 cd/m² was measured.

(3) Drive Durability

A continuous driving test was conducted under an initial luminance of 360 cd/m², and a time at which the luminance was reduced to a half was determined as a durable time.

### (Evaluation Results)

Obtained results are shown in Table 2.

Devices according to the invention were, in comparison with devices of comparative examples, higher in external quantum efficiency and elongated in particular in the drive durability.

Among these, as devices of examples 2, 3 and 9 were excellent in the drive durability, it shows that regions containing the second host material at such a very small amount as 5% by weight and 10% by weight exhibited a particularly excellent effect. The difference ΔIp of Ip values between two host materials is preferably in the range of 0.2 eV to 0.3 eV. In the case where the difference is too large as 0.6 eV and 0.7 eV as seen in examples 10, 11 and 13 to 15, the effect is slightly diminished.

Furthermore, while hole mobilities of all light-emitting layers in devices of comparative examples were larger than 1×10⁻⁴ cm²·V⁻¹·sec⁻¹, hole mobilities of all light-emitting layers in devices according to the invention were lower than 1×10⁻⁴ cm²·V⁻¹·sec⁻¹.

While the T1 of a compound B that is a light-emitting material was 65 Kcal/mol, the lowest triplet excitation level (T1) of a host material was, 67 Kcal/mol for mCP, 67 Kcal/mol for a compound F, 65 Kcal/mol for a compound A, 67 Kcal/mol for a compound C, 67 Kcal/mol for a compound D, 60 Kcal/mol for a compound G and 71 Kcal/mol for a compound E. That is, in combinations of host materials in the invention, at least one host material had a T1 value higher than that of the light-emitting material.

As the host materials, as shown in device Nos. 1, 4, 6, 10 and 13, a combination where the first host material is a carbazole compound and the second host material is a carbazole compound, an azepine compound or a carbene complex exhibited excellent performance.

TABLE 2

| | External Quantum | | |
|---|---|---|---|
| | Efficiency | Drive Voltage | Drive Durability |
| Device No. | (%) | (V) | (H) |
| Comparative 1 | 5.7 | 12 | 350 |
| Comparative 2 | 6.2 | 11 | 520 |
| Comparative 3 | 6.0 | 11 | 480 |
| Invention 1 | 7.5 | 13 | 1500 |
| Invention 2 | 7.8 | 14 | 1800 |
| Invention 3 | 7.3 | 12 | 1700 |
| Invention 4 | 7.8 | 13 | 1300 |
| Invention 5 | 7.9 | 14 | 1600 |
| Invention 6 | 7.0 | 12 | 1300 |
| Invention 7 | 7.1 | 13 | 1600 |
| Invention 8 | 8.5 | 14 | 1600 |
| Invention 9 | 8.8 | 15 | 1800 |
| Invention 10 | 7.4 | 11 | 1300 |
| Invention 11 | 7.4 | 12 | 1400 |
| Invention 12 | 7.1 | 10 | 1200 |
| Invention 13 | 8.1 | 12 | 1100 |
| Invention 14 | 8.0 | 13 | 1600 |
| Invention 15 | 7.8 | 11 | 1500 |
| Invention 16 | 7.5 | 10 | 1400 |

What is claimed is:

1. An organic electroluminescence device, comprising at least one light-emitting layer between a pair of opposing electrodes, wherein:
the light-emitting layer includes at least a light-emitting material and at least two host materials;
an Ip value (ionization potential) of a first host material is larger than an Ip value of a second host material;
a hole mobility of the first host material is larger than a hole mobility of the second host material; and
a content of the second host material is 1% by weight to 20% by weight of the total amount of host materials.

2. The organic electroluminescence device according to claim 1, wherein a difference in the Ip value (ΔIp) between the Ip value of the first host material and the Ip value of the second host material is from 0.2 eV to 1.0 eV.

3. The organic electroluminescence device according to claim 1, wherein a ratio of the hole mobility of the first host material to the hole mobility of the second host material is from 2 to 10,000.

4. The organic electroluminescence device according to claim 1, wherein the hole mobility of the light-emitting layer is from 1×10⁻⁷ cm²·V⁻¹·sec⁻¹ to 1×10⁻⁴ cm²·V⁻¹·sec⁻¹, in the case that an electric field of 1×10⁶ V/cm is applied to the light-emitting layer.

5. The organic electroluminescence device according to claim 1, wherein at least one of the light-emitting material is a phosphorescent material.

6. The organic electroluminescence device according to claim 5, wherein the lowest triplet excitation level (T1) of at least one of the at least two host materials is higher than T1 of the phosphorescent material.

7. The organic electroluminescence device according to claim 1, wherein the first host material is a carbazole compound, and the second host material is a carbazole compound, an azepine compound or a carbene complex compound.

8. The organic electroluminescence device according to claim 7, wherein a difference in the Ip value (ΔIp) between the Ip value of the first host material and the Ip value of the second host material is from 0.2 eV to 1.0 eV.

9. The organic electroluminescence device according to claim 7, wherein a ratio of the hole mobility of the first host material to the hole mobility of the second host material is from 2 to 10,000.

10. The organic electroluminescence device according to claim 7, wherein the hole mobility of the light-emitting layer is from 1×10⁻⁷ cm²·V⁻¹·sec⁻¹ to 1×10⁻⁴ cm²·V⁻¹·sec⁻¹, in the case that an electric field of 1×10⁶ V/cm is applied to the light-emitting layer.

11. The organic electroluminescence device according to claim 7, wherein at least one of the light-emitting material is a phosphorescent material.

12. The organic electroluminescence device according to claim 11, wherein the lowest triplet excitation level (T1) of at least one of the at least two host materials is higher than T1 of the phosphorescent material.
